(19) United States
(12) Patent Application Publication
(10) Pub. No.: US 2008/0265462 A1
(43) Pub. Date: Oct. 30, 2008

(54) PANEL/WAFER MOLDING APPARATUS AND METHOD OF THE SAME

(75) Inventors: Wen-Kun Yang, Hsin-Chu City (TW); Hsien-Wen Hsu, Lujhou City (TW); Ming-Chung Cheng, Fong Shan City (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 11/739,218

(22) Filed: Apr. 24, 2007

(51) Int. Cl. H01L 21/56

(52) U.S. Cl. 264/272.17; 425/141

(57) ABSTRACT

The present invention provides an apparatus and a method for panel/wafer molding. The present invention discloses a base with a first separation layer, an upper molding base with a second separation layer, a cheap molding layer and a vacuum panel bonding machine for bonding, a curing unit, a cleaning unit and a separating unit; wherein upper molding base is rectangular or round. Therefore the present invention providing a simple, cheap universal panel/wafer molding apparatus for a round or rectangular type panel, and does no harm to the chip active surface.

### FIELD OF THE INVENTION

The present invention relates to an apparatus and a method for panel/wafer molding, and more particularly to a simple apparatus and a method for panel/wafer molding.

### DESCRIPTION OF THE PRIOR ART

In the field of semiconductor devices, the device density is increased and the device dimension is reduced continuously. The demand for the packaging or interconnecting techniques for such high density devices is also increased.

Conventional package technologies have to divide a dice on a wafer into respective one and then packaging the die respectively, therefore, these techniques are time consuming for manufacturing process. Since the chip packaging technique is highly influenced by the development of integrated circuits, therefore, as the size of electronics has become demanding, so does the package technique. For the reasons mentioned above, the trend of package technique is toward ball grid array (BGA), flip chip (FC-BGA), chip scale package (CSP), Wafer level package (WLP) today. “Wafer level package” is a kind of technology that the entire packaging as well as other processing steps are carried out before singulating into single die. By wafer level packaging technology, we can produce die with extremely small dimensions and good electrical properties.

Though the advantages of WLP technique mentioned above, some issues still exist influencing the acceptance of WLP technique. Traditionally panel/wafer molding process requires a molding machine composing upper and lower tools and forming molding layer by injection mold method, wherein the material for molding layer is epoxy type material. The traditional way for panel/wafer molding is expensive and the other shortcomings of these tools comprise: these tools needing long time to assemble, the wafer or panel is easily to be damaged during molding process, warp often happens during process and special tapes or tools are required for protecting the wafer and panel.

Therefore, it is desirable to develop a method and an apparatus for cheap, easy molding without doing damage to a wafer/panel.

### SUMMARY OF THE INVENTION

One advantage of the present invention is providing a simple universal panel/wafer molding apparatus.

One advantage of the present invention is providing a simple panel/wafer molding process.

One advantage of the present invention is providing a simple panel/wafer molding apparatus and method for forming a round or rectangular type panel.

One advantage of the present invention is providing a simple panel/wafer molding apparatus and method for separating the molded panel.

Another advantage of the present invention is that the shape, for example thickness and flatness, of the molded panel is adjustable and controllable.

Another advantage of the present invention is that the molding process does no harm to the chip active surface.

Another advantage of the present invention is that no warp happens during the process.

Another advantage of the present invention is that the molding material can be liquid compound, liquid epoxy, resin, silicon rubber with or without filter.

The present invention provides an apparatus for panel/wafer molding, comprising: a base with a first separation layer applied thereon for placing dice, an upper molding base with a second separation layer on the bottom surface; a vacuum chamber; a microprocessor for controlling the molding process. The apparatus further comprises a component for mechanical and/or optical alignment and a component for curing. The upper molding base is round or rectangular. The microprocessor is programmed for controlling thickness and flatness of the molding layer.

The present invention provides a method for panel/wafer molding, comprising: providing a base with a first separation layer for placing dice; applying a molding layer covering the dice and filling into the space between the die; bonding an upper molding base, which is rectangular or round, on the upper surface of the molding layer by vacuum panel bonding, shaping the molding layer; curing the molding material for forming a panel; separating the panel from the first separation layer; separating the panel from the second separating layer of the upper base panel. The molding layer is formed by vacuum printing and made by liquid compound, liquid epoxy, resin, silicon rubber with or without filter; moreover, the thickness and flatness of the molding layer is controlled by program. The vacuum bonding is performed in vacuum chamber, controlled by mechanical and/or optical alignment process and the magnitude and time of force applied is controlled by program.

### BRIEF DESCRIPTION OF THE DRAWINGS

FIG. 1 is a schematic diagram of sawed dice redistributed on a redistribution tool according to the present invention.

FIG. 2 is a schematic diagram of a molding material applied on dice and fill into the space between the die according to the present invention.

FIG. 3 illustrates a step of pushing an upper molding base down for bonding and controlling the thickness of the molding layer according to the present invention.

FIG. 4 is a schematic diagram of an upper molding base bonding on the upper surface of the molding layer according to the present invention.

FIG. 5 illustrates a step of separating process for panel/wafer molding according to the present invention.

FIG. 6 illustrates another step of separating process for panel/wafer molding according to the present invention.

FIG. 7 illustrates block diagram of the apparatus according to the present invention.

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying claims.

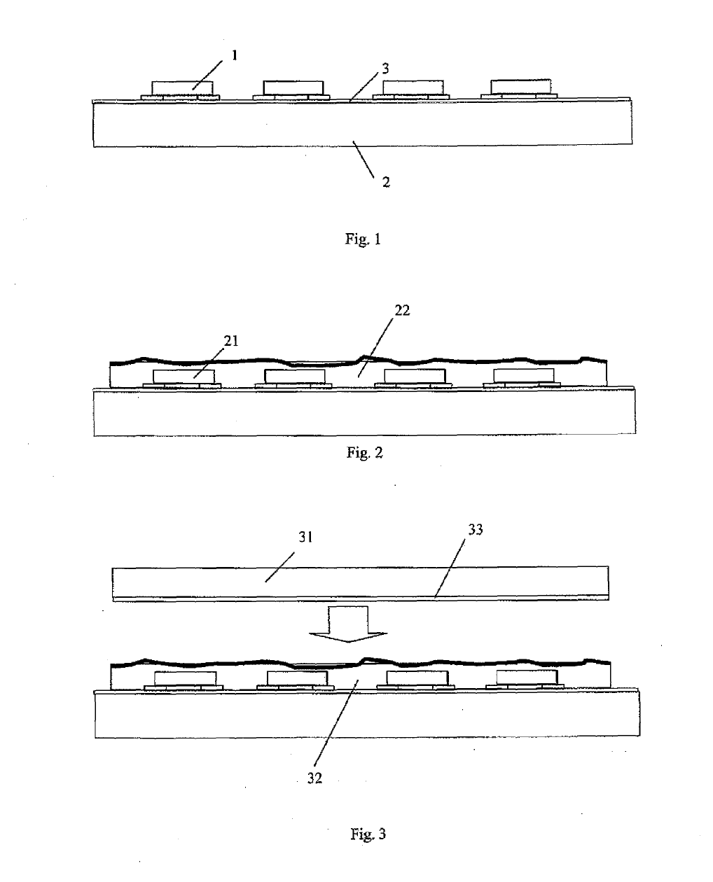

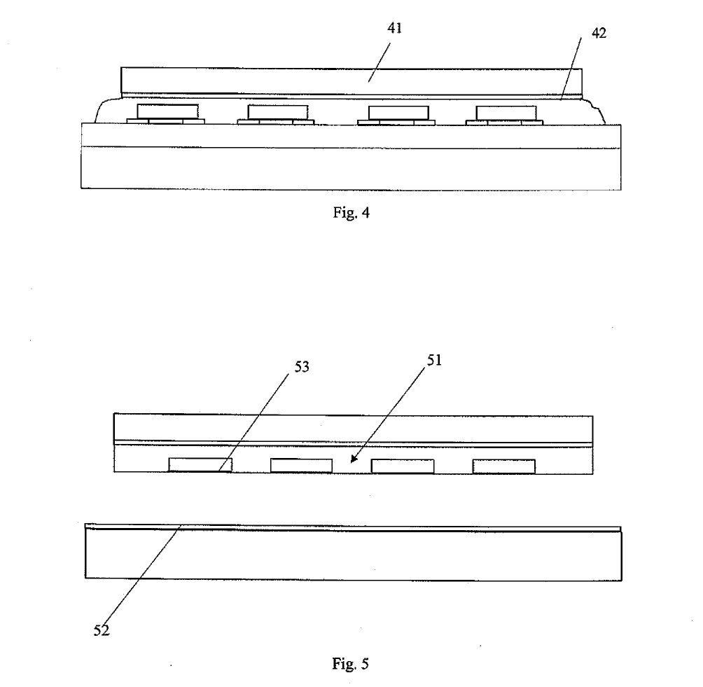

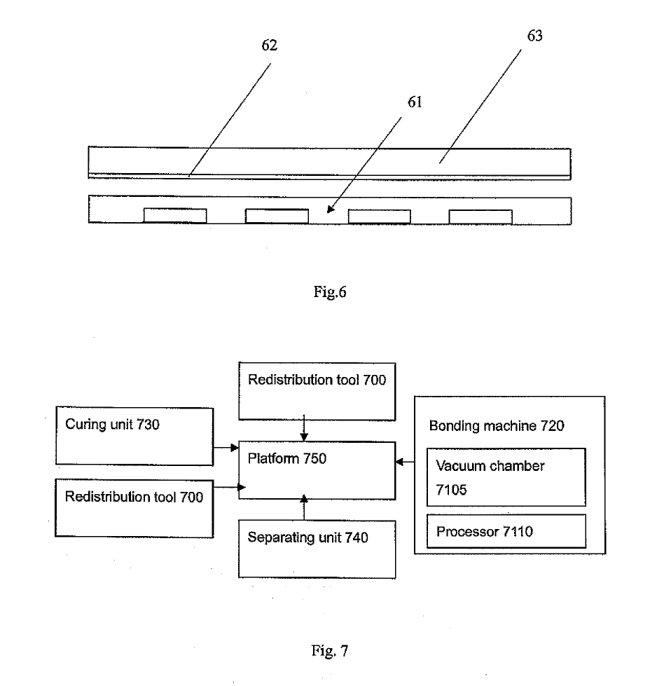

The present invention discloses a method for panel/wafer molding. As shown in FIG. 1, Sawed dice 1 are redistributed on the redistribution tool by pick and place with fine alignment system; wherein the base 2 of the redistribution tool comprises a first separation layer 3 with alignment patterns formed thereon and the dice are fixed on the first separation layer face down with patterned glue. As shown in FIG. 2, then a molding material is applied to cover the dice 21 and fill into the space between the die by vacuum printing method for forming a molding layer 22; the molding materials can be liquid compound, liquid epoxy, resin, or silicon rubber with or without filter. Next, as shown in FIG. 3, an upper molding base 31 is bonded on the upper surface of the molding layer 32 by vacuum panel bonding machine; wherein the molding layer 32 is made by simple materials and a second separation layer 33 formed at the bottom of the upper molding base 31. In one preferred embodiment of the present invention, the bonding is vacuum panel bonding; wherein the vacuum bonding is performed in vacuum chamber for preventing bubbles forming inside the molding layer. At next step, as shown in FIG. 4, the upper molding base 41 is pushed down for controlling the thickness of the molding layer 42; therefore excess glue would squeeze outside the edges of the upper molding base 41. In one preferred embodiment of the present invention, the thickness control is controlled by program to control the flat and thickness of the molding layer. In another embodiment of the present invention, the bonding process is controlled by mechanical and/or optical alignment process. In another embodiment of the present invention, the bonding process is controlled by program to control the magnitude and time of force applied. Next, the molding layer is cured and then a panel composed of the upper molding base, molding layer and die is formed, As shown is FIG. 5, at next step, excess glue is removed for forming rectangular or round shaped panel 51 and then the panel is separated from the first separation layer 52 of redistribution tool. After the surface of the panel 53 is cleaned, as shown in FIG. 6, the panel 61 is separated from the second separation layer 62 of upper base panel 63 by mechanical force; then a molded panel is completed.

Turning to FIG. 7, the present invention discloses an apparatus for panel/wafer molding comprising a redistribution tool 700, a vacuum panel bonding machine 710, a curing unit 720, a cleaning unit 730 and a separating unit 740. All the elements mentioned above are coupled to a platform 750 for processing the semiconductor device. The redistribution tool 700 is used for placing sawed dice by pick and place with fine alignment system; wherein the base of the redistribution tool 700 comprises a first separation layer with alignment patterns formed thereon and the dice are fixed on the first separation layer face down with patterned glue. A molding layer is formed by covering the die and filling into the space between the die with molding material; the molding materials can be liquid compound, liquid epoxy, resin, or silicon rubber with or without filter.

The vacuum panel bonding machine 710 of the present invention is used for bonding an upper molding base on the upper surface of the molding layer. The vacuum panel bonding machine 710 comprises an upper molding base and a vacuum chamber 7105, and a microprocessor 7110. A second separation layer is formed at the bottom of the upper molding base. The vacuum panel bonding machine 710 is equipped with a vacuum chamber for performing vacuum panel bonding. In another preferred embodiment of the present invention, the vacuum panel bonding machine 710 performs thickness control, wherein the thickness control is controlled by program to control the flat and thickness of the molding layer. In another preferred embodiment of the present invention, the thickness and flatness of the molding layer is controlled by the magnitude and time of force applied. In another preferred embodiment of the present invention, the vacuum panel bonding machine align upper molding layer with molding layer; wherein the alignment is controlled by an unit performing mechanical and/or optical alignment.

The curing unit 720 of the apparatus for panel/wafer molding performs curing process for forming a panel composed of an upper molding base, molding layer and die. The cleaning unit 730 of the apparatus for panel/wafer molding performs removing process for shaping the panel into round or rectangular shape or/and for cleaning the surface of the panel, for example, by solution. In another preferred embodiment of the present invention, the separating unit 740 performs separating process, for example, preceded by mechanical force, for separating the panel from the second separation layer.

Although preferred embodiments of the present invention have been described, it will be understood by those skilled in the art that the present invention should not be limited to the described preferred embodiments. Rather, various changes and modifications can be made within the spirit and scope of the present invention, as defined by the following claims.

Having described the invention, the following is claimed:

1. An apparatus for panel/wafer molding, comprising:
a platform for carrying a redistribution tool having dice on a lower base with a first separation layer applied thereon for placing dice, wherein an alignment pattern formed on said first separation layer;
an upper molding base with a second separation layer on the bottom surface;
a vacuum chamber coupled to said platform to provide predetermined processing condition;
a cleaning unit coupled to said platform; and
a microprocessor for controlling the molding process.

2. The apparatus of claim 1, further comprising a curing unit coupled to said platform.

3. The apparatus of claim 1, further comprising a component for mechanical and/or optical alignment.

4. The apparatus of claim 1, wherein said upper molding base is round or rectangular.

5. The apparatus of claim 1, wherein said microprocessor is programmed for controlling thickness and flatness of a molding layer.

6. The apparatus of claim 1, wherein the magnitude and time of force applied by said upper molding base is controlled by program.

7. The apparatus of claim 1, wherein said cleaning unit cleans the active surface of said die by solution.

8. A method for panel/wafer molding, comprising:
providing a base with a first separation layer for placing die,
applying a molding layer covering said die and filling into the space between said die,
bonding a second separation layer of an upper molding base with on the upper
surface of the molding layer by vacuum panel bonding,
curing said molding material for forming a panel;
shaping said panel;
separating said panel form said first separating layer of said base;
cleaning the active surface of said dice;
separating said panel form said second separating layer of said upper base panel.

9. The method of claim 8, wherein said molding layer is formed by vacuum printing.

10. The method of claim 8, wherein said molding layer is liquid compound, liquid epoxy, resin, silicon rubber with or without filter.

11. The method of claim 8, wherein said vacuum bonding is performed in vacuum chamber.

12. The method of claim 8, wherein the thickness and flatness of said molding layer is controlled by program.

13. The method of claim 8, wherein said bonding is controlled by mechanical and/or optical alignment process.

14. The method of claim 8, wherein said bonding is controlled by program to control the magnitude and time of force applied.

15. The method of claim 8, wherein said shaping shapes said panel into rectangular or round shape.

16. The method of claim 8, wherein said cleaning is performed with solution.
